(19) United States
(12) Patent Application Publication
(10) Pub. No.: US 2026/0293551 A1
(43) Pub. Date: Sep. 24, 2026

(54) SUBSTRATE PROCESSING METHOD AND METHOD OF MANUFACTURING CAPACITOR

(71) Applicant: KABUSHIKI KAISHA TOSHIBA, Kawasaki-shi (JP)

(72) Inventors: Hiroki KAWAKAMI, Kanazawa (JP); Susumu OBATA, Yokohama (JP); Kazuhito HIGUCHI, Yokohama (JP); Takayuki TAJIMA, Sagamihara (JP)

(73) Assignee: KABUSHIKI KAISHA TOSHIBA, Kawasaki-shi (JP)

(21) Appl. No.: 19/559,275

(22) Filed: Mar. 6, 2026

(30) Foreign Application Priority Data
Mar. 21, 2025 (JP) 2025-046712

(51) Int. Cl. H10P 50/24; H10D 1/00

(52) U.S. Cl. CPC H10P 50/242; H10D 1/042

(57) ABSTRACT

According to one embodiment, a substrate processing method includes forming a mask having an opening on a substrate including a semiconductor; forming at least one columnar body at a portion located in the opening of the mask on the substrate by dry etching using a reaction gas; forming a metal catalyst on the at least one columnar body; and removing the at least one columnar body by metal-assisted etching using the metal catalyst to form a recess.

### CROSS-REFERENCE TO RELATED APPLICATIONS

This application is based upon and claims the benefit of priority from Japanese Patent Application No. 2025-046712, filed Mar. 21, 2025, the entire contents of which are incorporated herein by reference.

### FIELD

Embodiments described herein relate generally to a substrate processing method and a method of manufacturing a capacitor.

### BACKGROUND

Etching is known as a method for forming a hole or a groove in a substrate such as a semiconductor wafer. Examples of the etching include a metal-assisted etching (also called metal-assisted chemical etching (MacEtch)) method. The metal-assisted etching (MacEtch) method is, for example, an etching method using a noble metal or the like as a catalyst. In a case where a trench having a high aspect ratio is processed in a substrate containing Si by this method, a processing defect such as porous Si occurs near an upper end portion of the trench.

### BRIEF DESCRIPTION OF THE DRAWINGS

FIG. 1 is a cross-sectional view schematically illustrating a structure obtained by forming a mask in a method of an embodiment.

FIG. 2 is a cross-sectional view schematically illustrating a structure obtained by patterning the mask in the method of the embodiment.

FIG. 3 is a cross-sectional view schematically illustrating a structure obtained by forming a protective layer in the method of the embodiment.

FIG. 4 is a cross-sectional view schematically illustrating a structure obtained by dry etching in the method of the embodiment.

FIG. 5 is a cross-sectional view schematically illustrating a structure obtained by forming a metal catalyst in the method of the embodiment.

FIG. 6 is a cross-sectional view schematically illustrating a structure obtained by metal-assisted etching in the method of the embodiment.

FIG. 7 is a cross-sectional view schematically illustrating a structure of a recess of a substrate processed by the method of the embodiment.

FIG. 8 is a cross-sectional view schematically illustrating a structure of a capacitor manufactured by the method of the embodiment.

FIG. 9 is a cross-sectional view schematically illustrating a structure obtained by forming a first metal catalyst in a method of a comparative example.

FIG. 10 is a cross-sectional view schematically illustrating a structure obtained by first metal-assisted etching in the method of the comparative example.

FIG. 11 is a cross-sectional view schematically illustrating a structure obtained by forming a second metal catalyst in the method of the comparative example.

FIG. 12 is a cross-sectional view schematically illustrating a structure obtained by second metal-assisted etching in the method of the comparative example.

FIG. 13 is an electron micrograph illustrating a vicinity of an upper end of a trench processed by the method of the comparative example.

### DETAILED DESCRIPTION

According to one embodiment, a substrate processing method includes:
forming a mask having an opening on a substrate including a semiconductor;
forming at least one columnar body at a portion located in the opening of the mask on the substrate by dry etching using a reaction gas;
forming a metal catalyst on the at least one columnar body; and
removing the at least one columnar body by metal-assisted etching using the metal catalyst to form a recess.

According to the embodiments, it is possible to provide a substrate processing method and a method of manufacturing a capacitor capable of reducing processing defects.

Hereinafter, the embodiments will be described in detail with reference to the accompanying drawings. Constituents which achieve the same or similar functions are denoted by the same reference numerals throughout the drawings, and repetitive descriptions will be omitted.

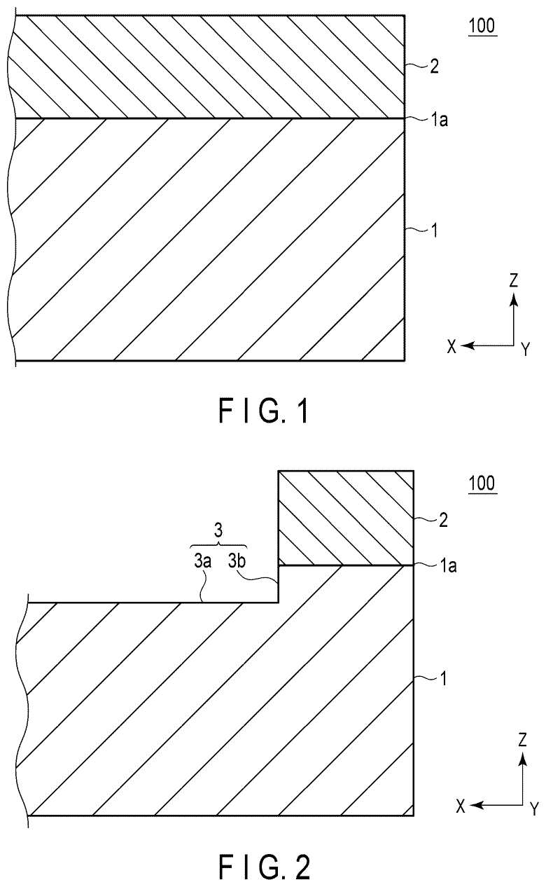

An example of a substrate processing method of an embodiment will be described with reference to FIGS. 1 to 7. In each drawing, a processed surface to be etched is parallel to the xy plane. The processed surface may be, for example, a main surface of a substrate. The x axis, the y axis, and the z axis cross each other perpendicularly. In addition, an object to be processed by the substrate processing method of the embodiment is referred to as treated substrate, for convenience.

### First Step

A mask having an opening is formed on a substrate containing a semiconductor.

The semiconductor is, for example, silicon (Si); germanium (Ge); a semiconductor formed of a compound of a group III element and a group V element, such as gallium arsenide (GaAs) or gallium nitride (GaN); and silicon carbide (SiC). According to an example, the substrate containing a semiconductor is a substrate containing silicon. The term “group” used herein is a “group” in the short-form periodic table.

The substrate containing a semiconductor may be, for example, a semiconductor substrate. The semiconductor substrate is, for example, a semiconductor wafer. The semiconductor wafer may be doped with an impurity, and may be formed with a semiconductor element such as a transistor or a diode. Further, a main surface of the semiconductor wafer may be parallel to any crystal plane of the semiconductor. A usable semiconductor wafer is, for example, a silicon wafer whose main surface is a (100) plane or a silicon wafer whose main surface is a (110) plane.

The first step will be described with reference to FIGS. 1 and 2.

As illustrated in FIG. 1, a mask layer 2 is deposited on a main surface 1a of a substrate 1 containing a semiconductor (hereinafter, referred to as substrate 1), the main surface 1a being parallel to the xy plane. The semiconductor includes, for example, Si. The substrate 1 may have any shape. Here, as an example, the substrate 1 is a single-crystal silicon wafer. A plane orientation of the single-crystal silicon wafer is not particularly limited. In FIG. 1, a silicon wafer whose main surface 1a is a (100) plane is used as the substrate 1. As the substrate 1, a silicon wafer whose main surface is a (110) plane can also be used.

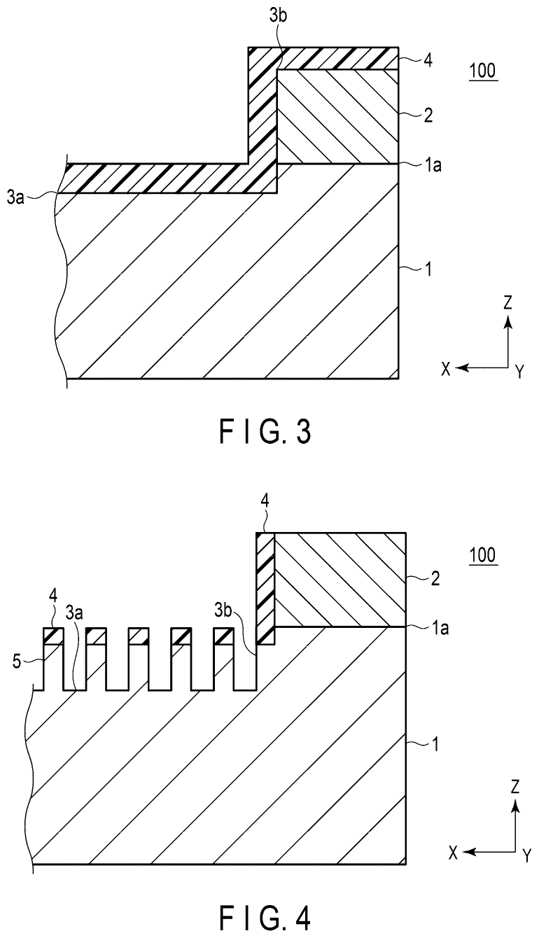

Next, as illustrated in FIG. 2, one or more openings 3 are formed in the mask layer 2 by patterning the mask layer 2. The patterning is performed by, for example, etching. A shape of the opening 3 is not particularly limited. The opening 3 has, for example, a groove shape extending in the y-axis direction and having a depth in the z-axis direction. A number of the openings 3 is not limited, and can be one or more. The opening 3 has a rectangular shape defined by a bottom inner surface 3a and a side wall surface 3b in a cross section along the z-axis direction. In FIG. 2, only one side in the x-axis direction of the opening 3 and a substrate portion in the vicinity thereof is illustrated. The same omission is made in FIGS. 3 to 6. The position of the bottom inner surface 3a of the opening 3 is not the same as a boundary between the mask layer 2 and the main surface 1a of the substrate 1, but is closer to the substrate 1 than the boundary. The opening 3 can be formed by etching the substrate 1 along with etching of the mask layer 2 by, for example, over etching.

The mask layer 2 desirably includes a material having a low etching rate with respect to a reaction gas used in dry etching and having high resistance to hydrofluoric acid. Such a material is difficult to be etched by dry etching, and thus can protect the substrate 1 as a mask also in metal-assisted etching in addition to serving as a mask in a Bosch process described later, and contributes to reducing processing defects. Examples of the material for the mask layer 2 include inorganic materials such as negative photoresist or silicon nitride. Examples of silicon nitride include Si₃N₄.

The mask layer 2 may be formed by, for example, an existing semiconductor process. The mask layer 2 made of an organic material may be formed by, for example, photolithography. The mask layer 2 made of an inorganic material may be formed by, for example, formation of an inorganic material layer by a vapor deposition method, formation of a mask by photolithography, and patterning of the inorganic material layer by etching. Alternatively, the mask layer 2 made of an inorganic material may be formed by oxidation or nitridation of the surface region of the substrate 1, formation of a mask by photolithography, and patterning of an oxide or nitride layer by etching.

### Second Step

At least one columnar body is formed in a portion located in the opening of the mask on the substrate containing a semiconductor by dry etching using a reaction gas.

It is desirable to form a protective layer as passivation before dry etching. The protective layer is also referred to as passivation layer.

The second step will be described with reference to FIGS. 3 and 4.

In a treated substrate 100, as illustrated in FIG. 3, a protective layer 4 covers the bottom inner surface 3a and the side wall surface 3b of the opening 3, and the mask layer 2 adjacent to the opening 3. As described above, the opening 3 penetrates the mask layer 2 in a thickness direction (z-axis direction), and the bottom inner surface 3a of the opening 3 is located inside the main surface 1a of the substrate 1, and also located near the other main surface side. Therefore, an end portion of the protective layer 4 covering the bottom inner surface 3a is in contact with the side wall surface 3b of the opening 3. As a result, it is possible to suppress etching processing of the side wall surface 3b of the opening 3 at the time of dry etching, and thus, to reduce processing defects of the side wall surface 3b of the opening 3.

The protective layer 4 desirably has resistance to hydrogen fluoride (HF). This makes it possible to suppress dissolution of the protective layer 4 in an etching agent for metal-assisted etching. As a result, it is possible to suppress precipitation of the metal catalyst for metal-assisted etching on the side wall surface 3b. For the protective layer 4, for example, a fluorocarbon polymerized film can be used. Examples of the fluorocarbon polymerized film can include a polymerized film represented by (—CF₂—)ₙ. The fluorocarbon polymerized film can be produced, for example, by reacting a reaction gas on the treated substrate 100 using plasma chemical vapor deposition (CVD). Examples of the reaction gas can include C₄F₈ gas.

Next, dry etching using a reaction gas is performed. Examples of dry etching include reactive ion etching. Examples of the reaction gas can include SF₆ alone and a mixed gas of SF₆ and O₂.

The formation of the protective layer and the dry etching are desirably performed according to a Bosch process. According to this method, the etching processing proceeds toward a region immediately below a place where the protective layer has reacted with the reaction gas (in the z-axis direction). A place where the etching processing does not proceed remains as a columnar body immediately below the opening 3. The at least one columnar body can be formed at the main surface 1a of the substrate 1 by performing the protective layer formation by the Bosch process and the dry etching by the Bosch process at least once, preferably alternately a plurality of times in an etching apparatus. An example of a structure obtained in this step is illustrated in FIG. 4. As a result of etching processing of a substrate portion located immediately below the opening 3 in a depth direction (z-axis direction), the recess communicating with the opening 3 is processed. The bottom inner surface of the recess is located below the opening 3. In order to facilitate understanding of the relationship between the opening 3 and the recess, reference numeral 3a is used for the bottom inner surface of the recess, and reference numeral 3b is used for the side wall surface thereof. A plurality of columnar bodies 5 extend in the depth direction (z-axis direction) from the bottom inner surface 3a of the recess. Each columnar body 5 is a nanorod having a cylindrical shape. There is a gap between the columnar bodies 5. A part of the protective layer 4 has been removed by dry etching, but the remaining protective layer 4 exists at a tip of each columnar body 5, on the side wall surface 3b of the recess, and on a surface (for example, the inner surface) of the mask layer 2. The protective layer 4 covering the side wall surface 3b of the recess or the surface of the mask layer 2 can suppress precipitation of a metal catalyst for metal-assisted etching on the side wall surface 3b of the recess. By forming the columnar body 5 by dry etching, it is possible to suppress generation of a diffusion layer by the metal catalyst on the substrate 1. As a result, it is possible to suppress the occurrence of a processing defect at the side wall surface 3b of the recess.

The columnar body 5 illustrated in FIG. 4 has a columnar shape, but the shape of the columnar body 5 is not particularly limited. The columnar body 5 can have a structure having a height in the depth direction (z-axis direction) of the recess. Other examples of the shape of the columnar body 5 can include a needle shape, a conical shape, and a truncated conical shape. All the columnar bodies 5 may have the same shape, or may be composed of a plurality of types of columnar bodies 5 having different shapes.

A number of the columnar bodies 5 present in the recess can be 1 or more. A plurality of columnar bodies 5 are preferably present, and a gap is preferably present between the columnar bodies 5. When a gap exists between the columnar bodies 5, diffusion of a gas (for example, hydrogen gas) generated at the time of metal-assisted etching becomes smooth, so that it is possible to suppress peeling of the metal catalyst from the columnar bodies 5. As a result, the etching processing proceeds uniformly, and thus the recess parallel to the thickness direction (z-axis direction) of the substrate 1 can be processed.

The columnar body 5 is desirably a nanorod. One example of the nanorod is a columnar body having dimensions on the order of nanometers.

A length of the columnar body 5 is desirably 100 nm or more and 350 nm or less. When the length of the columnar body 5 is short, the metal catalyst particles formed on the columnar body 5 have a shape close to a spherical shape, so that the layer of the metal catalyst particles has a substantially film shape. When the layer of the metal catalyst particles has a substantially film shape, the layer of the metal catalyst particles is easily peeled off from the columnar body 5 by a gas (for example, hydrogen gas) generated by metal-assisted etching. Since the etching processing is less likely to proceed at a place where the layer of the metal catalyst particles is peeled off, there is a possibility that a defect such as a failure in processing a recess substantially perpendicular to the main surface 1a of the substrate 1 occurs. On the other hand, when the length of the columnar body 5 is too long, the amount of the metal catalyst to be precipitated (or deposited) on the columnar body 5 increases, and thus, there is a possibility that the precipitation of the metal catalyst on the side wall surface 3b of the recess is promoted. By setting the length of the columnar body 5 to 100 nm or more and 350 nm or less, it is possible to increase the proportion of vertically long particles long in the recess depth direction (z-axis direction) in the metal catalyst particles formed on the columnar body 5 while suppressing the precipitation of the metal catalyst on the side wall surface 3b of the recess. Therefore, a three-dimensional metal catalyst layer having irregularities in the depth direction (z-axis direction) can be formed.

A width of the columnar body 5 is desirably 50 nm or less. The width of the columnar body 5 is a width in a direction intersecting a length direction of the columnar body 5.

The length and the width of the columnar body 5 can be measured, for example, by observing a cross section along the thickness direction (z-axis direction) of the treated substrate 100 subjected to the second step with a scanning electron microscope (SEM). The width of the columnar body 5 is a width in a direction perpendicularly intersecting the length direction of the columnar body 5 at a lower end of the columnar body 5 (bottom inner surface 3 a side).

The protective layer formation and the dry etching by the Bosch process can be performed under the following conditions, for example.

The treated substrate 100 subjected to the first step is set in a chamber of a reactive ion etching (RIE) apparatus, and passivation treatment is performed under conditions of a pressure in the chamber of 15 mTorr, a flow rate of C₄F₈ gas as the reaction gas of 100 sccm, an output of a plasma generation coil of 800 W, and a treatment time of 5 seconds, whereby a fluorocarbon polymerized film can be formed on the mask layer 2 and the recess of the treated substrate 100.

Subsequently, with the treated substrate 100 set in the chamber of the reactive ion etching (RIE) apparatus, dry etching treatment is performed under conditions of a pressure in the chamber of 15 mTorr, a mixed gas of SF₆ gas and O₂ gas as the reaction gas, an SF₆ gas flow rate of 100 sccm, an O₂ gas flow rate of 13 sccm, an output of a plasma generation coil of 800 W, and a treatment time of 6 seconds, whereby the columnar body 5 can be formed in the recess of the treated substrate 100. The length of the columnar body 5 can be controlled by the number of cycles of the protective layer formation and the dry etching. As an example, the columnar body 5 having a length of about 300 nm can be formed by 50 cycles.

### Third Step

A metal catalyst is formed on the at least one columnar body.

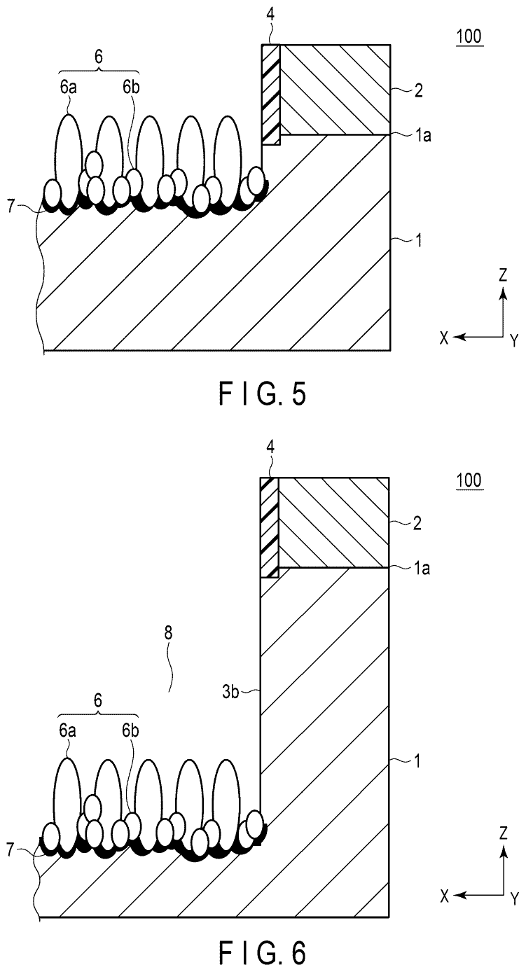

The third step will be described with reference to FIG. 5.

FIG. 5 illustrates an example of a structure obtained in the third step. A plurality of columnar bodies 5 exist in the recess of the treated substrate 100. Metal catalyst particle layers 6 are precipitated on surfaces of the columnar bodies 5 and in gaps between the columnar bodies 5, whereby the entire surfaces of the columnar bodies 5 are covered with the metal catalyst particle layers 6. Therefore, no columnar body 5 is exposed on the treated substrate 100. Since the columnar body 5 is covered with the metal catalyst particle layer 6 and is not exposed to the outside, the columnar body 5 can be removed by metal-assisted etching, and the recess can be processed in a direction (z-axis direction) perpendicular to the main surface 1a of the substrate 1. On the substrate 1 located in the vicinity of the metal catalyst particle layer 6, there is a diffusion layer 7 generated by diffusion of the metal catalyst into the substrate 1. The protective layer 4 covering the tips of the columnar bodies 5 may be peeled off from the columnar bodies 5 by formation of the metal catalyst particle layer 6. The protective layer 4 covering the side wall surface 3b of the recess and the mask layer 2 can exist even after the formation of the metal catalyst particle layer 6. It can be confirmed by, for example, SEM observation that the columnar bodies 5 are covered with the metal catalyst particle layer 6.

The metal catalyst particle layer 6 is a layer containing first metal catalyst particles 6a and second metal catalyst particles 6b. The first metal catalyst particles 6a have, for example, an ellipsoidal shape, a conical shape, and a flat shape. The second metal catalyst particles 6b have, for example, a spherical shape or a substantially spherical shape. It can also be said that the first metal catalyst particles 6a are vertically long particles longer than the second metal catalyst particles 6b in the z-axis direction. In metal catalyst particle layer 6, the first metal catalyst particles 6a and the second metal catalyst particles 6b are randomly distributed in the in-plane direction. As a result, the metal catalyst particle layer 6 has a three-dimensional structure having irregularities in the z-axis direction. As a result, the etching processing proceeds in the direction (z-axis direction) perpendicular to the main surface 1a of the substrate 1, so that a recess perpendicular to the main surface 1a of the substrate 1 can be processed.

The metal catalyst of the metal catalyst particle layer 6 desirably contains at least one selected from the group consisting of Au, Ru, Ag, Pt, and Pd. The metal catalyst desirably contains Au.

The metal catalyst particle layer 6 is desirably formed by, for example, sputtering, vapor deposition, chemical vapor deposition, or electroless plating. Electroless plating is preferred. Examples of electroless plating can include displacement plating. When the metal catalyst particle layer 6 is formed by displacement plating, a plurality of columnar bodies 5 exist in a state of being spaced from each other, and thus displacement plating proceeds at almost the entire columnar bodies 5. Therefore, the metal catalyst particle layer 6 having irregularities in the z-axis direction, corresponding to the shape of the columnar body 5, can be formed.

A displacement plating solution used in displacement plating is a mixed solution of a salt of the metal catalyst and hydrofluoric acid. The displacement plating solution is, for example, a mixed solution of an aqueous solution of tetrachloroauric (III) acid, an aqueous solution of gold sulfite, or an aqueous solution of potassium gold cyanide (I), and hydrofluoric acid. Hydrofluoric acid can remove a native oxide film on the surface of the substrate.

### Fourth Step

The at least one columnar body is removed by metal-assisted etching using a metal catalyst to form a recess.

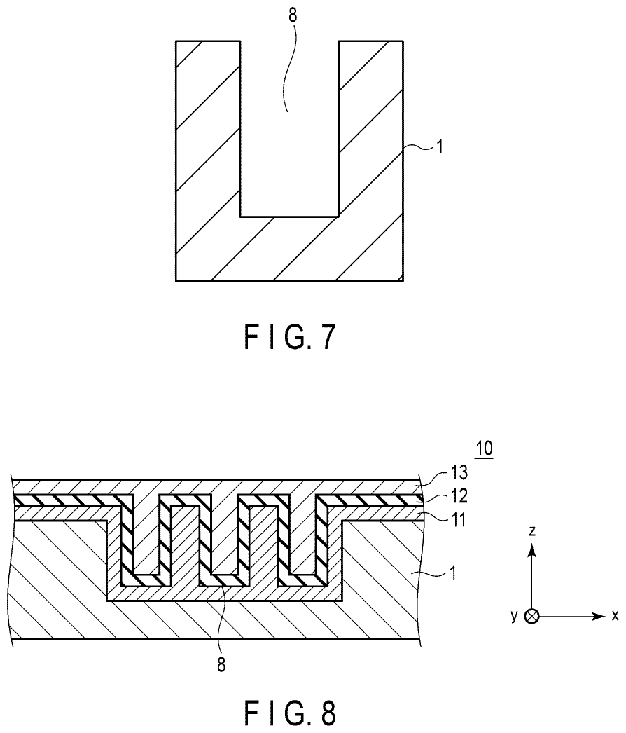

Hereinafter, the fourth step will be described with reference to FIGS. 6 and 7.

The metal-assisted etching is also called metal-assisted chemical etching (MacEtch).

The treated substrate 100 subjected to the third step is, for example, immersed in a liquid etching agent to bring the etching agent into contact with the treated substrate 100. Details of the etching agent will be described below.

The etching agent contains an oxidizer and hydrogen fluoride (hydrofluoric acid). A specific example of the etching agent is an aqueous solution containing an oxidizer and hydrogen fluoride.

The oxidizer can be selected at least one of from, for example, hydrogen peroxide, nitric acid, AgNO₃, KAuCl₄, HAuCl₄, K₂PtCl₆, H₂PtCl₆, Fe(NO₃)₃, Ni(NO₃)₂, Mg(NO₃)₂, Na₂S₂O₈, K₂S₂O₈, KMnO₄ and K₂Cr₂O₇. Hydrogen peroxide is preferred as the oxidizer because it does not produce a harmful byproduct.

A concentration of hydrogen fluoride (hydrofluoric acid) in the etching agent can be, for example, 6.5 mol/L or more and 8.0 mol/L or less. A concentration of hydrogen peroxide in the etching agent can be, for example, 1.5 mol/L or more and 2.5 mol/L or less. The concentration is set within the above range, so that a speed of the etching can be increased. Therefore, a recess having a high aspect ratio can be processed with high productivity.

The etching agent may further contain a buffer. The buffer contains, for example, at least one of ammonium fluoride or ammonia. According to an example, the buffer is ammonium fluoride. According to another example, the buffer is a mixture of ammonium fluoride and ammonia.

The etching agent may further contain any other component such as water.

An example of a structure obtained by MacEtch using the metal catalyst described above is illustrated in FIG. 6. According to MacEtch, a semiconductor material contained in a region close to the metal catalyst particle layer 6, for example, the columnar body 5 and the bottom inner surface of the recess, here, silicon is oxidized. The resulting oxide is dissolved and removed by hydrofluoric acid. Therefore, only a portion close to the metal catalyst particle layer 6 is selectively etched. Since the first metal catalyst particles 6a of the metal catalyst particle layer 6 have a shape extending in a direction substantially perpendicular to the main surface 1a of the substrate 1, a substrate portion located immediately below the metal catalyst particle layer 6 can be selectively etched. Therefore, a portion of the substrate 1 located in the opening 3 can be processed into a recess having a high aspect ratio and having a depth direction in a direction intersecting (for example, perpendicular to) the main surface 1a of the substrate 1.

Further, since the metal catalyst component is diffused in the substrate portion located in the vicinity of the metal catalyst particle layer 6, the diffusion layer 7 of the metal catalyst is present. On the other hand, the protective layer 4 exists near an upper end of the side wall surface 3b defining the recess. The protective layer 4 can suppress precipitation of the metal catalyst. As a result, a processing defect (for example, a porous defect) in which the side wall surface 3b is etched can be suppressed. Therefore, for example, as illustrated in FIG. 7, a recess 8 having a high aspect ratio can be processed with high productivity.

The treated substrate 100 after the etching is separated from the etching agent by, for example, pulling it up from the etching agent. Thereafter, the treated substrate may be washed. The mask layer or the metal catalyst can be removed as necessary.

As necessary, certain steps may be omitted.

FIGS. 5 and 6 illustrate a simplified structure for easy understanding. Actually, in the plating treatment for generating the first metal catalyst particles 6a or the second metal catalyst particles 6b, the catalyst particles may be connected to each other. Therefore, the first metal catalyst particles 6a and the second metal catalyst particles 6b do not necessarily have a structure in which the two types of particles can be clearly distinguished from each other as illustrated in the drawings.

The substrate processing method of the embodiment described above includes: forming a mask having an opening on a substrate containing a semiconductor; forming at least one columnar body at a portion located in the opening of the mask on the substrate by dry etching using a reaction gas; forming a metal catalyst on the at least one columnar body; and removing the at least one columnar body by metal-assisted etching using the metal catalyst to form a recess. According to this method, the columnar bodies are formed by dry etching instead of metal-assisted etching, and thus diffusion in and precipitation on the substrate, of the metal catalyst, can be suppressed. Therefore, it is possible to suppress the occurrence of a processing defect at the side wall surface of the recess, when the recess is processed by metal-assisted etching. In addition, by forming the metal catalyst on the at least one columnar body, metal-assisted etching can be selectively advanced along the length direction of the at least one columnar body. Therefore, the recess having a depth in a direction intersecting a processed surface (for example, a main surface) of the substrate can be processed without occurrence of a processing defect.

A capacitor can be manufactured using a substrate in which a recess is processed by the processing method described above. A method of manufacturing a capacitor will be described with reference to FIG. 8.

A capacitor 10 illustrated in FIG. 8 includes a substrate 1 having a plurality of recesses 8, and a conductive layer 13 formed on an inner surface of each of the recesses 8 of the substrate 1 via a dielectric layer 12.

The substrate 1 is a Si wafer having a doped layer 11 doped with a P-type or N-type impurity in one main surface. A plurality of recesses (trenches) 8 are provided in one main surface of the substrate 1. The recesses (trenches) 8 are processed by the method of the embodiment. A depth direction of each recess (trench) 8 is along the z-axis direction. For the substrate 1 having the structure described above, the dielectric layer 12 is provided on the main surface of the substrate 1 and the inner surface of each of the recesses 8. Next, the capacitor 10 can be manufactured by embedding the conductive layer 13 in the recess 8 in which the dielectric layer 12 is provided on its inner surface.

The dielectric layer 12 is made of, for example, an organic dielectric or an inorganic dielectric. As the organic dielectric, for example, polyimide can be used. As the inorganic dielectric, a ferroelectric can also be used, and examples of the inorganic dielectric layer can include an oxide film and a nitride film. Paraelectrics such as silicon nitride, silicon oxide, silicon oxynitride, titanium oxide, or tantalum oxide are preferable.

The conductive layer 13 is formed of, for example, poly-Si (poly-silicon) doped with impurities. Examples of the impurities can include P-type or N-type impurities. The conductive layer 13 is not limited to poly-Si, and may be formed of, for example, a metal or an alloy such as molybdenum, aluminum, gold, tungsten, platinum, nickel, or copper.

### Comparative Example

It will be described with reference to a comparative example that processing defect occurs when the columnar body is formed by metal-assisted etching instead of dry etching.

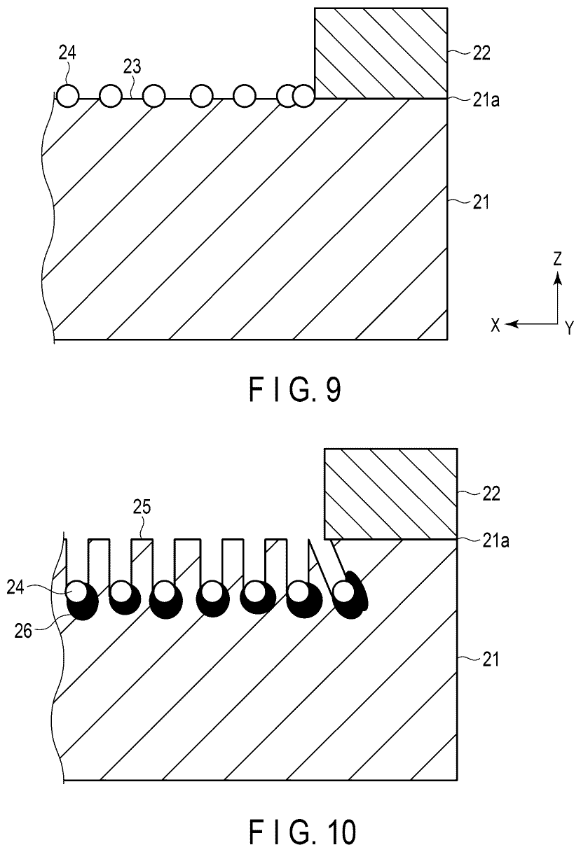

A comparative example will be described with reference to FIGS. 9 to 13.

A silicon wafer 21 whose main surface 21a is a (100) plane was prepared. Next, a mask layer 22 having an opening 23 was formed on the main surface 21a of this silicon wafer. The mask layer 22 was formed by photolithography using a photoresist.

An aqueous solution of tetrachloroauric (III) acid and hydrofluoric acid were mixed to prepare a displacement plating solution. This displacement plating solution had a tetrachloroauric (III) acid concentration of 0.0005 mmol/L and a hydrogen fluoride concentration of 1 mol/L. A substrate 21 with the mask layer 22 formed thereon was immersed in a displacement plating solution to form a first Au catalyst particle layer 24. A structure formed by this displacement plating is illustrated in FIG. 9.

Next, hydrofluoric acid and hydrogen peroxide were mixed to prepare an etching agent. The etching agent had a hydrogen fluoride concentration of 3.8 mol/L and a hydrogen peroxide concentration of 0.5 mol/L. The substrate 21 where the mask layer 22 and the first Au catalyst particle layer 24 were formed was immersed in the etching agent and etched. As a result, a recess was formed as illustrated in FIG. 10, and a needle-shaped Si 25 was formed at the bottom inner surface of the recess. An Au diffusion layer 26 was formed in a substrate portion located in the vicinity of the first Au catalyst particle layer 24.

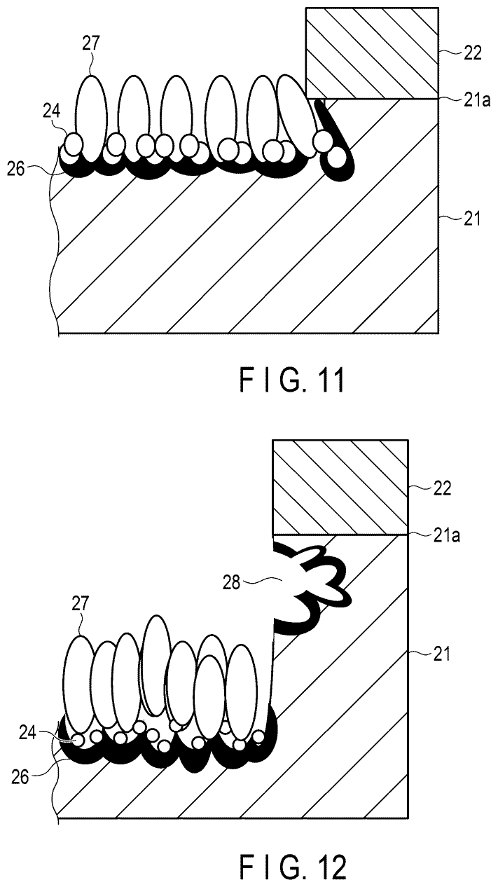

An aqueous solution of tetrachloroauric (III) acid and hydrofluoric acid were mixed to prepare a displacement plating solution. This displacement plating solution had a tetrachloroauric (III) acid concentration of 0.003 mmol/L and a hydrogen fluoride concentration of 1 mol/L. The substrate where the mask layer 22, the first Au catalyst particle layer 24, and the needle-shaped Si 25 were formed was immersed in the displacement plating solution to form a second Au catalyst particle layer 27. A structure obtained by this displacement plating is illustrated in FIG. 11. As illustrated in FIG. 11, the second Au catalyst particle layer 27 had a columnar shape extending in the depth direction of the trench. The Au diffusion layer 26 was present on the entire inner surface of the trench.

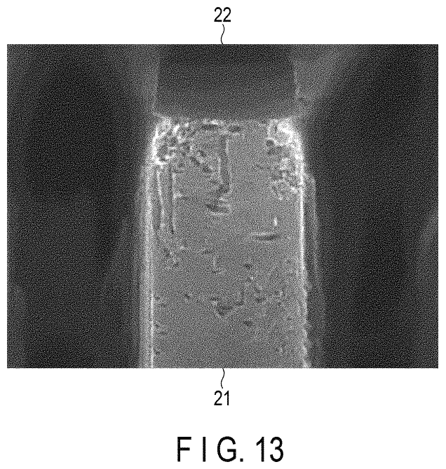

Next, hydrofluoric acid and hydrogen peroxide were mixed to prepare an etching agent. The etching agent had a hydrogen fluoride concentration of 7.5 mol/L and a hydrogen peroxide concentration of 2 mol/L. The substrate where the mask layer 22, the second Au catalyst particle layer 27, and the needle-shaped Si 25 were formed was immersed in the etching agent and etched. As illustrated in FIG. 12, the obtained trench had a porous shape 28 near the upper end of the wall surface. FIG. 13 shows an enlarged view of a scanning electron micrograph (SEM photograph) of the vicinity of the upper end of the wall surface of the trench obtained by the method of the comparative example. The trench has a predetermined aspect ratio, but a depression (dent) is generated near the upper end of the wall surface of the trench. It is presumed that Si was dissolved by the action of the Au diffusion layer 26 or the Au catalyst particles present near the upper end of the wall surface of the trench.

The substrate processing method of at least one of the embodiments described above includes: forming a mask having an opening on a substrate containing a semiconductor; forming at least one columnar body at a portion located in the opening of the mask on the substrate by dry etching using a reaction gas; forming a metal catalyst on the at least one columnar body; and removing the at least one columnar body by metal-assisted etching using the metal catalyst to form a recess. Therefore, this method enables processing of the recess having a depth in a direction intersecting the processed surface of the substrate without occurrence of a processing defect.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate processing method comprising:
forming a mask having an opening on a substrate comprising a semiconductor;
forming at least one columnar body at a portion located in the opening of the mask on the substrate by dry etching using a reaction gas;
forming a metal catalyst on the at least one columnar body; and
removing the at least one columnar body by metal-assisted etching using the metal catalyst to form a recess.

2. The substrate processing method according to claim 1, wherein the metal catalyst comprises at least one selected from the group consisting of Au, Ru, Ag, Pt, and Pd.

3. The substrate processing method according to claim 2, wherein the metal catalyst is formed on the at least one columnar body by sputtering, vapor deposition, chemical vapor deposition, or electroless plating.

4. The substrate processing method according to claim 1, wherein the at least one columnar body has a needle shape, a cylindrical shape, a conical shape, or a truncated conical shape.

5. The substrate processing method according to claim 1, wherein the forming at least one columnar body is forming a plurality of the columnar bodies spaced apart from each other at the portion located in the opening of the mask on the substrate by dry etching using the reaction gas.

6. The substrate processing method according to claim 5, wherein a length of the columnar bodies is 100 nm or more and 350 nm or less.

7. The substrate processing method according to claim 6, wherein a width of the columnar bodies is 50 nm or less.

8. The substrate processing method according to claim 5, wherein the forming metal catalyst is covering the columnar bodies with particles of the metal catalyst.

9. The substrate processing method according to claim 1, wherein the semiconductor comprises Si.

10. A method of manufacturing a capacitor, the method comprising:
forming a recess in a substrate comprising a semiconductor by the substrate processing method according to claim 1; and
forming a conductive portion in the recess via a dielectric layer.

11. The method according to claim 10, wherein the semiconductor comprises Si.
